(19) United States
(12) Patent Application Publication
(10) Pub. No.: US 2008/0218951 A1
(43) Pub. Date: Sep. 11, 2008

(54) Protection Panel for Electronic Apparatus Display Window and Production Method for Protection Panel

(76) Inventors: Yasuji Kusuda, Kyoto (JP); Takao Hashimoto, Kyoto (JP); Jun Shimizu, Kyoto (JP); Shinya Yamada, Kyoto (JP)

Correspondence Address: WENDEROTH, LIND & PONACK, L.L.P., 2033 K STREET N. W., SUITE 800, WASHINGTON, DC, 20006-1021, US

(21) Appl. No.: 10/589,668

(22) PCT Filed: Feb. 17, 2005
(86) PCT No.: PCT/JP2005/002409

§ 371 Date: Aug. 16, 2006

(30) Foreign Application Priority Data
Feb. 20, 2004 (JP) 2004-045512

(51) Int. Cl. H05K 5/00

(52) U.S. Cl. 361/681

(57) ABSTRACT

To provide a low reflectance protection panel with decoration for a display window of an electronic apparatus, superior in productivity. A decorating film is laminated on the surface of a transparent protective plate: the decorating film forms at least a window forming layer having a transparent window portion on the surface of a hard coating film at the transparent protective plate side and is formed with a low reflectance processed layer on the opposite surface thereof: and a low reflectance processed layer is formed on the rear surface of the transparent protective plate. Or, a decorating film is laminated on a surface of an optical isotropic transparent protective plate being interposed by a polarizing plate, the decorating film forms at least a window forming layer having a transparent window portion on the surface of the hard coating film at the transparent protective plate side.

### TECHNICAL FIELD

The present invention relates to a display window protection panel for an electronic apparatus fitted into a display window opening for protecting a portion of a display device, which is located under the display window opening in a casing of the electronic apparatus and exposed therefrom, and a manufacturing method of the protection panels.

### BACKGROUND ART

Generally, casings of electronic apparatuses such as mobile phones and smart phones have a flat shape constructed of a combination of a front casing and a back casing made of a synthetic resin. Specifically, the front casing is formed with an opening for a display window for disposing a liquid crystal display device, or the like, and to protect the surface of the display device provided below the display window, a protection panel is fixed by fusion bonding, or the like.

Previously, various ideas have been proposed for the protection panel. For example, Japanese Laid-Open Patent Publication No. 2002-72214 discloses such a constitution that, in order to solve such a disadvantage that a liquid crystal display is extremely poor in viewability in well-lit rooms and outdoors due to reflection, a protection panel is formed in a combination of a λ/4 plate, a polarizing plate, and a transparent protective plate. Such arts are also disclosed that additional functions are added to the outermost surface of the protection panel by constructing the transparent protective plate as a touch panel and sticking a hard coating film or a low reflectance film thereon.

Moreover, recently, as electronic apparatuses have become fashionable in design, a decoration such as edging is made on the protection panel by printing as disclosed in Japanese Laid-Open Patent Publication No. 2001-318612.

[Patent document 1] Japanese Laid-Open Patent Publication No. 2002-72214

[Patent document 2] Japanese Laid-Open Patent Publication No. 2001-318612

### DISCLOSURE OF INVENTION

### [Problems to be Solved by the Invention]

However, to print a decoration on the protection panel, printing has to be carried out on each of the formed protection panels after forming the protection panel. Therefore, there is such a problem that the above is disadvantageous in productivity.

Accordingly, an object of the present invention is to solve the above disadvantage and to provide a display window protection panel for an electronic apparatus, which is superior in productivity, and a manufacturing method of the protection panels.

### [Means for Solving the Problem]

To achieve the above object, according to a first aspect of the present invention, A display window protection panel for an electronic apparatus fitted into a display window opening for protecting a portion of a display device, which is located under the display window opening in a casing of the electronic apparatus and exposed from the display window opening, the protection panel comprising:

a transparent protective plate provided being opposed to a surface of the exposed portion of the display device;

a decorating film including a transparent hard coating film and a window forming layer having a decorating portion formed in a thin film state in a portion of one surface of the hard coating film and a part where is not formed with the decorating portion and is formed as a transparent window portion arranged so that the portion exposed from the display window opening of the display device can be viewed; and

a transparent sticking layer for sticking the decorating film to a surface at a side not facing to the display device of the transparent protective plate in a laminated state so that the window forming layer is positioned at a surface side of the transparent protective plate is provided.

According to a second aspect of the present invention, the display window protection panel for an electronic apparatus according to the first aspect, wherein the decorating portion is provided in a peripheral area of the decorating film as a printed layer, and the transparent window portion is formed in an central portion of the decorating film is provided.

According to a third aspect of the present invention, the display window protection panel for an electronic apparatus according to the first aspect, wherein the decorating film is further provided with a first low reflectance processed layer is provided.

According to a fourth aspect of the present invention, the display window protection panel for an electronic apparatus according to the third aspect, wherein the first low reflectance processed layer is provided to an entire of the other surface of the hard coating film is provided.

According to a fifth aspect of the present invention, the display window protection panel for an electronic apparatus according to the first aspect, wherein the transparent protective plate is optical isotropic, and either surface thereof is provided with a polarizing film is provided.

According to a sixth aspect of the present invention, the display window protection panel for an electronic apparatus according to the fifth aspect, wherein the polarizing film is provided to a surface at a transparent protective plate side not opposing to the display device is provided.

According to a seventh aspect of the present invention, the display window protection panel for an electronic apparatus according to the fifth aspect, wherein the transparent protective plate is provided with a second low reflectance processed layer onto a surface at a side opposing to the display device is provided.

According to a eighth aspect of the present invention, the display window protection panel for an electronic apparatus according to the seventh aspect, wherein the second low reflectance processed layer is formed of a λ/4 plate is provided.

According to a ninth aspect of the present invention, the display window protection panel for an electronic apparatus according to any one of aspects, wherein the transparent protective plate is constructed of a touch panel including a movable electrode film laminated on the decorating film and a fixed electrode plate stuck to the movable electrode film in the peripheral portion thereof so as to form an air layer between the movable electrode film and the fixed electrode plate is provided.

According to a tenth aspect of the present invention, a manufacturing method of display window protection panels for an electronic apparatus fitted into a display window opening for protecting a portion of a display device, which is located under the display window opening in a casing of the electronic apparatus and exposed from the display window opening, the method comprising:

forming a plurality of decorating areas each including a window forming layer having a decorating portion formed in a portion of one surface of the hard coating film in a thin film state, in which a part not provided with the decorating portion is formed as a transparent window portion which transmits a portion of the display device exposed from the display window opening so as to be viewed, thereby producing a large size decorating film;

sticking the large size decorating film to a large size transparent protective plate having an area larger than one of the decorating areas so that the decorating portion is located opposing to a surface of the large size transparent protective plate; and

cutting the stuck large size decorating film and large size transparent protective plate at one time in a position outer than the transparent window portion as well as inner side of the decorating area, thereby obtaining protection panels is provided.

### EFFECT OF THE INVENTION

Since the display window protection panel for an electronic apparatus according to the present invention is constructed as described above, the following effects can be obtained.

That is, in the display window protection panel for an electronic apparatus according to the present invention, since the decorating film, which is previously formed with the window-forming layer having the transparent window portion on the rear surface of the hard coating film, is stuck onto the transparent protective plate surface in a lamination state, each protection panel does not have to be printed. Moreover, by arranging as described above, when carrying out the printing on the hard coating film, which is the object to be formed with the window forming layer, since a plurality of patterns can be continuously printed using a rolled film, when manufacturing the protection panel, by sticking a large size decorating film and a large size transparent protective plate to each other and cutting them at one time, the productivity of the protection panels can be increased. Further, since the window forming layer is disposed between the hard coating film and the transparent protective plate and is not exposed to the outside, the printing on the decorating portion is not deteriorated due to the use for a long period of time. Furthermore, since the decorating portion is formed as a thin film and projections and recessions are not formed on the surface of the decorating film, such a disadvantage does not occur that, causes air bubbles to be caught between the transparent protective plate and the decorating film while sticking them to each other.

### BRIEF DESCRIPTION OF DRAWING

FIG. 1 is a cross-sectional view of a display window protection panel for an electronic apparatus according to an embodiment of the present invention, taken along the line I-I in FIG. 6;

FIG. 2 is a cross-sectional view of a display window protection panel for an electronic apparatus according to another embodiment of the present invention;

FIG. 3 is a cross-sectional view of a display window protection panel for an electronic apparatus according to still another embodiment of the present invention;

FIG. 4 is a cross-sectional view of a display window protection panel for an electronic apparatus according to still another embodiment of the present invention;

FIG. 5 is a cross-sectional view of a display window protection panel for an electronic apparatus according to still another embodiment of the present invention;

FIG. 6 is a view showing the external structure of the display window protection panel for an electronic apparatus according to the embodiments of the present invention;

FIG. 7 is a view showing an example use of the display window protection panel for an electronic apparatus according to the embodiments of the present invention; and

FIG. 8 is a view showing a manufacturing process of the display window protection panel for an electronic apparatus according to the embodiments of the present invention.

### BEST MODE FOR CARRYING OUT THE INVENTION

Before the description of the present invention proceeds, it is to be noted that like parts are designated by like reference numerals throughout the accompanying drawings. Hereinafter, the present invention will be described further in detail with reference to the drawings.

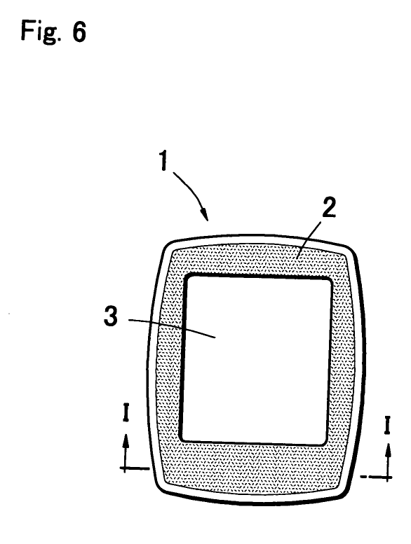

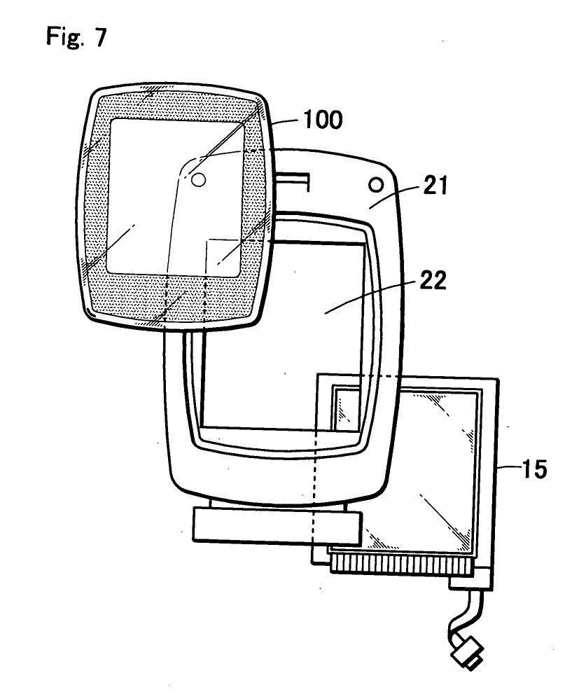

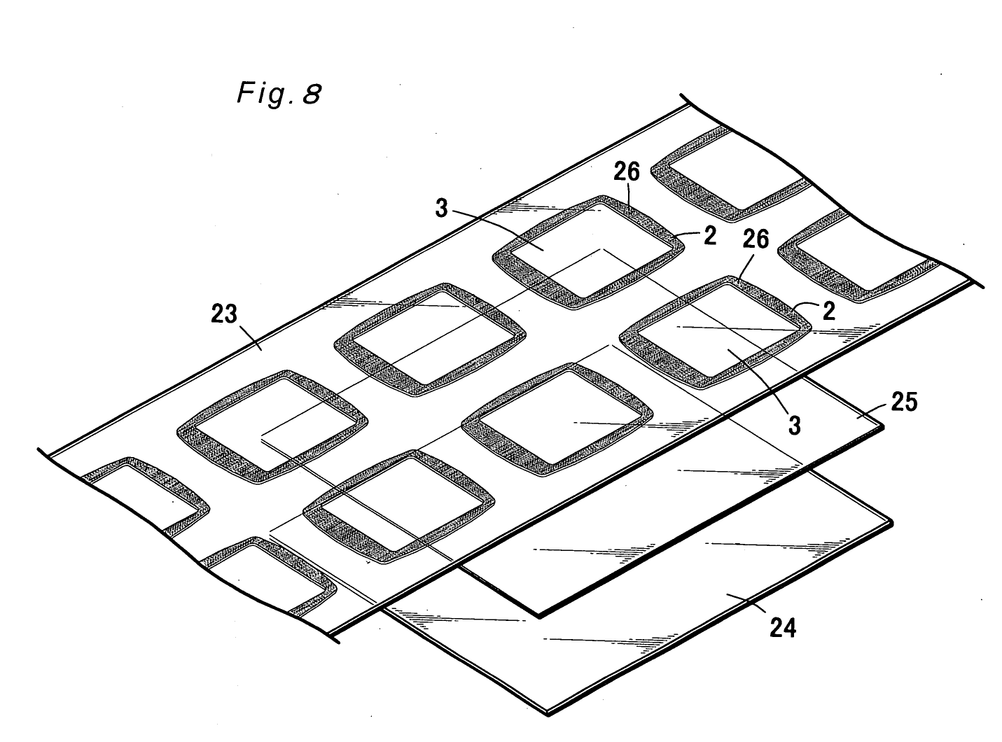

The display window protection panel for an electronic apparatus according to the present invention is a thin resin panel as shown in FIG. 6, and is provided for covering an opening for a display window of a casing of an electronic apparatus as shown in FIG. 7. That is, a front casing 21 is formed with an opening for a display window 22 for disposing a liquid crystal display device 15, or the like, the protection panel is fixed by fusion bonding, or the like to protect the surface of the mounted display device 15 below the display window opening 22.

The display window protection panel 1 for an electronic apparatus is constructed of a decorating portion 2 and a transparent window portion 3. When the protection panel is disposed on the display window of an electronic apparatus, the liquid crystal panel 15 mounted below the protection panel 1 can be viewed through the transparent window portion 3. The decorating portion 2 is formed of a decorating film 7 including a window forming layer 6 having decorating at the periphery area of the protection panel as described later, and the part of the forming layer 6 formed with no decorating is the transparent window portion 3. Therefore, the decorating film 7 may be provided on the entire surface of the protection panel. The decorating portion 2 may be produced by sticking the decorating film 7 with the window forming layer to the surface of the transparent protective plate constituting the protection panel, and then, cutting the transparent protective plate 4 and the decorating film 7 at one time.

For example, as shown in FIG. 8, the protection panel may be produced by sticking a rolled decorating film 23, on which a plurality of decorating areas 26 each includes a decorating portion 2, to a large size transparent protective plate 24 using a transparent double-sided tape 25 and then cutting the stuck transparent protective plate and the decorating film at one time. The stuck large size transparent protective plate 24 and the rolled decorating film 23 are cut at one time preferably at a position outside the transparent window portion 3 and inside the decorating area 26. By arranging as described above, the protection panel in which the decorating layer 2 is formed up to the edge portion thereof can be produced.

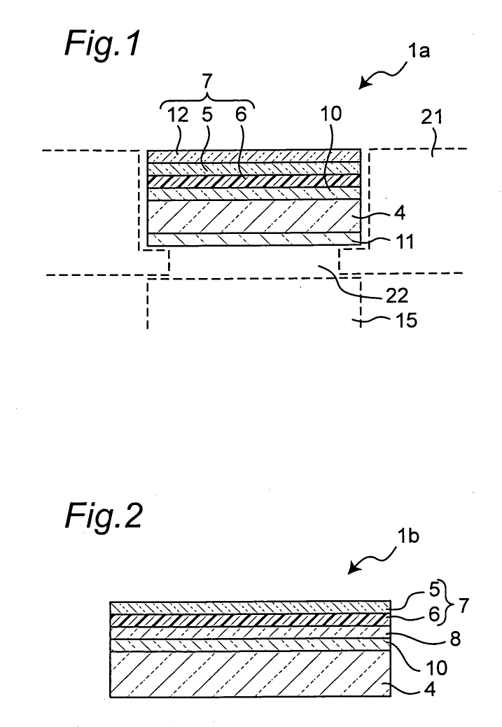

The protection panel shown in FIG. 6 has a laminated structure of the transparent protective plate 4 and the decorating film 7; and specifically has, for example, a cross-sectional structure as shown in FIG. 1.

In a protection panel 1a shown in FIG. 1, the decorating film 7 is stuck onto the surface of the transparent protective plate 4 into a laminated state by means of a sticking layer 10; and on the rear surface of the transparent protective plate 4, a second low reflectance processed layer 11 is formed. Also, in the decorating film 7, on the surface of hard coating film 5 at the transparent protective plate 4 side, the window forming layer 6 having the decorating portion 2 is formed, and on the opposite surface thereof, a first low reflectance processed layer 12 is formed.

If some kind of optical reflection can be reduced and the viewability of the display of the liquid crystal panel 15 viewed through the transparent window portion can be increased, the first and second low reflectance processed layers 12 and 11 may have any structures respectively.

For the transparent protective plate 4, a material that excels in transparency and is capable of protecting the liquid crystal panel 15 from breakeage is used. For example, general-purpose resins such as polystyrene resin, polyolefin resin, ABS resin, AS resin, acrylic resin, and AN resin, and the like are given. Moreover, the following resins may be used: general-purpose engineering resins such as polystyrene resin, polycarbonate resin, polyacetal resin, polycarbonate denatured polyphenylene ether resin, polybutylene terephthalate resin, and ultra high molecular weight polyethylene resin, and the like; or super engineering resins such as polysulfone resin, polyphenylene sulfide resin, polyphenylene oxide resin, polyarylate resin, polyetherimide resin, polyimide resin, liquid crystal polyester resin, and polyallyl heat-resistant resin, and the like.

To form the second low reflectance processed layer 11 located on the rear surface of the transparent protective plate 4, the following low reflectance processing method may be employed. For example, applying a low reflectance material using resin with low refractive index such as fluorocarbon resin or silicone resin; forming a metal multilayered film by deposition or the like; sticking a low reflectance film; or processing the surface into a satin finished surface by applying of sand blasting, embossing, matte coating, etching or the like, are employed.

As the hard coating film 5 of the decorating film 7, such a film is used that a hard coating processed layer of acrylic resin, silicone resin, UV curing resin, or the like is formed on one or both surfaces of a transparent resin film formed of an engineering plastic such as polycarbonate, polyamide, polyether keton, and the like; or acryl, polyethylene terephthalate, polybutylene terephthalate or the like. When the hard coating processed layer is formed on only one surface thereof, the surface formed with no hard coating processed layer comes to the transparent protective plate 4 side.

To form the first low reflectance processed layer 12 of the decorating film 7, in the same manner as the formation of the second low reflectance processed layer 11 provided on the rear surface of the transparent protective plate 4, the following methods may be employed: that is, applying a low reflectance material using resin with low refractive index such as fluorocarbon resin or silicone resin; forming a metal multilayered film by vapor deposition or the like; sticking a low reflectance film; or processing the surface into a satin finished surface by applying of sand blasting, embossing, matte coating, etching, or the like. The timing of forming the first low reflectance processed layer 12 may be at a point either before or after forming the window forming layer 6 on the hard coating film 5.

The decorating film 7 includes the transparent window portion and the decorating portion. In the protection panel 1 obtained by laminating the decorating film 7 on the surface of the transparent protective plate 4, a portion to be decorated is the decorating portion 2 and the portion with no decorating portion 2 is the transparent window portion 3. By forming the decorating portion 2 only in the periphery area of the decorating film so that the transparent window portion 3 is formed in the central portion thereof, the decorating portion 2 may be used, for example, also as a concealing part for electrodes part provided in the periphery area of the liquid crystal panel 15.

As the material of the decorating portion of the window forming layer 6, a coloring ink, which contains a pigment or dye of an appropriate color as the coloring agent using the following resin as the binder: polyvinyl chloride resin, polyamide resin, polyester resin, polyacrylic resin, polyurethane resin, polyvinyl acetal resin, polyester urethane resin, cellulose ester resin, alkyd resin, or the like may be employed. As the method of forming the decorating portion, gravure printing, screen printing or the like is preferably employed. Little pits and projections are formed on the surface of the decorating film by printing to form the decorating portion in a thin film state on the window forming layer. Accordingly, when sticking the decorating film to the transparent protective plate, air bubbles are hardly formed between the transparent protective plate 4 and the decorating film 7.

The window forming layer 6 may be formed of a metal thin film layer or a combination of a printed layer and a metal thin film layer. The metal thin film layer is formed to give the window forming layer 6 a metallic luster, and may be formed by vacuum evaporation, sputtering, ion plating, plating, or the like. In this case, the following metals may be employed in accordance with the desired color of the metallic luster; i.e., metal such as aluminum, nickel, gold, platinum, chromium, iron, copper, tin, indium, silver, titanium, lead, zinc, or, an alloy of the above, or compounds. Normally, the metal thin film layer is formed partially. Also, when the metal thin film layer is formed, a pre-anchor layer or a post-anchor layer may be formed for improving adhesion to another layer.

As the sticking layer 10, whereas a transparent double-sided tape may be preferably used, a transparent adhesive agent may be employed. The sticking layer may be provided on the entire surface of the decorating film 7. However, the sticking layer may be provided only to a portion of the window-forming layer to be provided with the decorating portion to increase the viewability of the transparent window portion.

The productivity of the protection panels is increased according to the above constructions. That is, the decorating film 7 previously provides the window forming layer 6 having the decorating portion and the transparent window portion, on the rear surface of the hard coating film 5 and is laminated on the surface of the transparent protective plate 4. Therefore, the printing on each protection panel is not required. Moreover, a plurality of patterns can be continuously printed using the rolled film when providing the decorating portion on the hard coating film 5 or the transparent resin film 12 to be formed with the window forming layer 6. Therefore, the productivity of the protection panels can be increased.

The display window protection panel for an electronic apparatus according to the embodiment of the present invention is not limited to the above-described constitution. For example, a protection panel 1b shown in FIG. 2 is constructed by laminating a decorating film 7 on the surface of an optically isotropic transparent protective plate 4 with a polarizing plate 8 interposed therebetween (see FIG. 2). Note that, in this case, at least a window-forming layer 6, which has the decorating portion and the transparent window portion, is formed on the surface of the hard coating film 5 at the transparent protective plate 4 side. The reflected light from the liquid crystal panel 15 side can be reduced by the polarizing plate 8 disposed as described above. Also, the window-forming layer 6 is arranged so as to position in front of the polarizing plate 8 when the protection panel is mounted on an electronic apparatus. Accordingly, the viewability of the window-forming layer 6 is satisfactorily increased. Contrarily, if the window-forming layer 6 is positioned behind the polarizing plate 8, the window-forming layer 6 is viewed through the polarizing plate 8 resulting in an unsatisfactory viewability of the window-forming layer. As for the polarizing plate 8, a polarizing plate ordinarily used in the field of liquid crystal display may be employed. For example, such a uniaxial expanded film, in which a dichroic material such as iodine or a dichroic dye is absorbed and oriented in a polyvinyl alcohol resin, is suitable. Ordinarily, such a uniaxial expanded film, in which a dichroic material is absorbed and oriented, is used in a state a protective film is laminated on both surfaces thereof. When such protection panel is used, the polarizing plate provided to the liquid crystal panel 15 may be omitted.

As methods of decorating the display window protection panel of an electronic apparatus, Japanese Laid-Open Patent Publication No. 2001-318612 discloses transfer-inmolding and insert molding. The methods are applicable to the decorating on the transparent protective plate 4 only. However, the methods are not applicable to the above-described constitution including the polarizing plate 8. The reason of this is the polarizing plate 8 deteriorates due to the heat when a printed sheet is inserted in a mold and then molten resin is injected thereinto. When the decorating film 7 is laminated on the transparent protective plate 4 provided with the polarizing plate 8, the polarizing plate 8 never deteriorates.

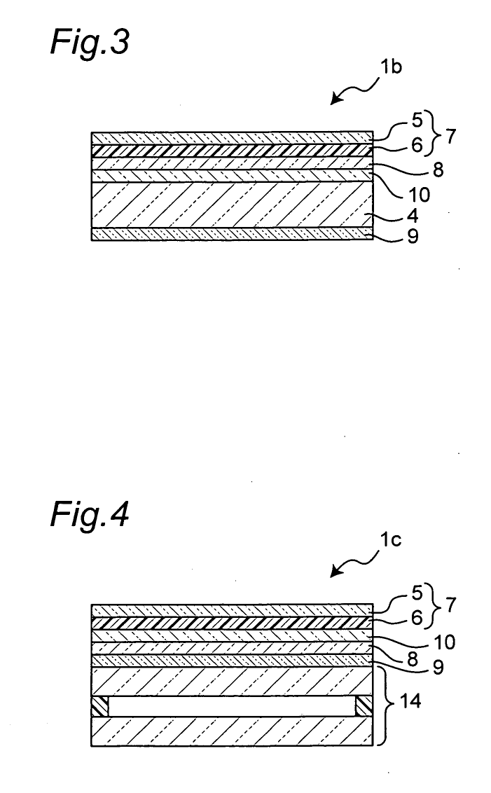

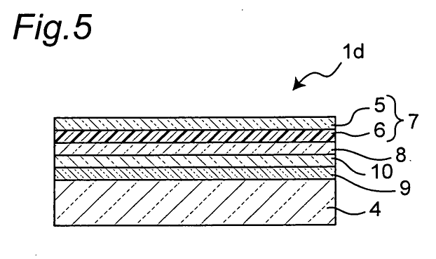

Also, in a display window protection panel 1c for an electronic apparatus according to another embodiment of the present invention, the constitution including the above-described polarizing plate 8 may be further laminated with a λ/4 plate 9 on the rear surface of the transparent protective plate 4 (see FIG. 3). The λ/4 plate 9 is a wavelength plate having a function to cause a phase difference of ¼ wavelength in the incident ray. The λ/4 plate 9 may be disposed between the polarizing plate 8 and the transparent protective plate 4 (see FIG. 5). The λ/4 plate 9 and the polarizing plate 8 are combined so that the optical axes thereof form an angle of approximately 45° with respect to each other and constitute circular polarizing plates. The circular polarizing plate functions as an anti-reflection filter that efficiently absorbs the internal reflection due to the incident light from the outside to increase the viewability.

The λ/4 plate 9 may be constituted of a uniaxial expanded film formed from various kinds of high molecular substances which are generally adopted in field of liquid crystal display. As examples of materials, polyvinyl alcohol, norbornene resin, cellulose resin, polycarbonate, and the like are given, but not limited thereto.

Moreover, in the above-described constitutions disposed with the polarizing plate 8, the transparent protective plate 4 may be constructed of a touch panel 14 (see FIG. 4). As the touch panel, the following widely used conventional touch panel may be employed. That is, the touch panel is constructed of a decorating film 7, a laminated movable electrode film, and a fixed electrode plate, which is stuck to the movable electrode film at the peripheral portion thereof to form an air layer therebetween.

Moreover, in the display window protection panel 1 for an electronic apparatus according to present invention, the decorating film 7 may be constructed of the window-forming layer 6 formed on the surface of the hard coating film 5 at the transparent protective plate 4 side with a transparent resin film interposed therebetween. In this case, the window-forming layer 6 may be formed after the transparent resin film is stuck to the hard coating film 5. Or, the transparent resin film, which has been formed with the window-forming layer 6 on the surface at the transparent protective plate 4 side, may be stuck to the hard coating film 5. Also, in the present invention, as the decorating film 7, such a decorating film that a transparent resin film, which has been provided with the window-forming layer 6 on the surface at the hard coating film 5 side and stuck onto the surface of the hard coating film 5 at the transparent protective plate 4 side, may be employed.

### FIRST WORKING EXAMPLE

Employing a single-sided hard coating film (low reflectance processed) of a PET base material of 0.075 mm in thickness, a window forming layer having a transparent window portion on the surface opposite to the hard coating surface was formed in a manner of gravure printing; thus the decorating film was prepared. Then, the decorating film was stuck to the surface of an optical isotropic transparent protective plate, which was made of acrylic plate of 1.0 mm in thickness, using a transparent double-sided tape so that the window forming layer side thereof was the rear surface, and a low reflectance film (manufactured by NOF CORPORATION) was stuck to the rear surface of the transparent protective plate; thus the low reflectance processed layer was formed.

The protection panel was constructed that the decorating film in which the window-forming layer having the transparent window portion had been previously formed on the rear surface of the hard coating film was laminated on the surface of the transparent protective plate. Accordingly, the productivity of the protection panels was satisfactorily increased.

### SECOND WORKING EXAMPLE

Employing a single-sided hard coating film of a PET base material of 0.075 mm in thickness, a window forming layer having a transparent window portion on the surface opposite to the hard coating surface was formed in a manner of gravure printing; thus the decorating film was prepared. Then, a polarizing plate (HEG1425DU manufactured by Nitto Denko Corporation), in which iodine had been absorbed and oriented in a polyvinyl alcohol resin of 0.2 mm in thickness, was stuck on the surface of an optical isotropic transparent protective plate made of an acrylic plate of 1.0 mm in thickness. Then, the decorating film was stuck to the surface of the polarizing plate using a transparent double-sided tape so that the window forming layer side became the rear surface. And further, a λ/4 plate (SEF340138B manufactured by Sumitomo Chemical Co. Ltd.) made of polycarbonate resin of 40 μm in thickness was stuck to the rear surface of the transparent protective plate, thus the display window protection panel of an electronic apparatus was obtained. Assuming that, in the orientation axis of the λ/4 plate and the absorption axis of the polarizing plate, the lateral direction be 0°; and that the angle change in the counterclockwise direction, the orientation axis of the λ/4 plate was 90°, and the absorption axis of the polarizing plate 2 was 45°. The above sticking was carried out entirely using a baseless transparent adhesive of 25 μn in thickness.

The protection panel was constructed that the decorating film in which the window-forming layer having the transparent window portion had been previously formed on the rear surface of the hard coating film was laminated on the surface of the transparent protective plate. Accordingly, the productivity of the protection panels was satisfactorily increased.

### THIRD WORKING EXAMPLE

The third working example was similar to the second working example excepting that the transparent protective plate was a touch panel as described below. That is, an ITO film of 20 nm in thickness was entirely formed on one surface of the polycarbonate film of 0.1 mm in thickness by sputtering and peripheral portion of the ITO film was removed, thus a transparent electrode having a square shape larger in width was formed. And a circuit including bus bars, which were disposed between the two edges opposite to each other in the lateral direction of the transparent electrode, and routing circuits for outputting from the bus bars to the outside was formed using a silver paste by screen printing. Further, an acrylic plate of 0.7 mm in thickness and having the identical vertical and lateral dimensions to those of the PET film was stuck onto the surface opposite to the surface formed with the transparent electrode of polycarbonate film using a baseless transparent adhesive of 25 μm in thickness, thus a lower side electrode plate was obtained. Also, using a polycarbonate film of 125 μm in thickness, which has vertical and lateral dimensions identical to those of the lower side electrode plate, an ITO film of 20 nm in thickness was formed on the entire one surface thereof by sputtering, and then a peripheral portion of the ITO film was removed; thus the transparent electrode having a square shape larger in width was formed. Further, a circuit including bus bars, which were disposed between the two edges opposite to each other in the vertical direction of the transparent electrode, and routing circuits for outputting to the outside from the bus bars was printed using a silver paste by screen printing; thus an upper electrode was obtained. The upper side electrode plate and the lower side electrode plate were disposed being parted from the electrodes and faced to each other, and stuck to each other in the peripheral area excluding a periphery portion of a film connector using an adhesive; thus a touch panel was obtained.

The protection panel was constructed that the decorating film in which the window-forming layer having the transparent window portion had been previously formed on the rear surface of the hard coating film was laminated on the surface of the transparent protective plate. Accordingly, the productivity of the protection panels was satisfactorily increased.

Effects of the respective embodiments can be obtained by appropriately combining arbitrary embodiments in the above-described embodiments.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1. A display window protection panel for an electronic apparatus fitted into a display window opening for protecting a portion of a display device, which is located under the display window openings in a casing of the electronic apparatus and exposed from the display window opening, said protection panel comprising:
a transparent protective plate provided being opposed to a surface of said exposed portion of said display device;
a decorating film including a transparent hard coating film and a window forming layer having a decorating portion formed in a thin film state in a portion of one surface of said hard coating film and a part where is not formed with said decorating portion and is formed as a transparent window portion arranged so that the portion exposed from said display window opening of said display device can be viewed; and
a transparent sticking layer for sticking said decorating film to a surface at a side not facing to said display device of said transparent protective plate in a laminated state so that said window forming layer is positioned at a surface side of the transparent protective plate.

2. The display window protection panel for an electronic apparatus according to claim 1, wherein said decorating portion is provided in a peripheral area of said decorating film as a printed layer, and said transparent window portion is formed in an central portion of said decorating film.

3. The display window protection panel for an electronic apparatus according to claim 1, wherein said decorating film is further provided with a first low reflectance processed layer.

4. The display window protection panel for an electronic apparatus according to claim 3, wherein said first low reflectance processed layer is provided to an entire of the other surface of said hard coating film.

5. The display window protection panel for an electronic apparatus according to claim 1, wherein said transparent protective plate is optical isotropic, and either surface thereof is provided with a polarizing film.

6. The display window protection panel for an electronic apparatus according to claim 5, wherein said polarizing film is provided to a surface at a transparent protective plate side not opposing to said display device.

7. The display window protection panel for an electronic apparatus according to claim 5, wherein said transparent protective plate is provided with a second low reflectance processed layer onto a surface at a side opposing to said display device.

8. The display window protection panel for an electronic apparatus according to claim 7, wherein said second low reflectance processed layer is formed of a λ/4 plate.

9. The display window protection panel for an electronic apparatus according to claim 1, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.

10. A manufacturing method of display window protection panels for an electronic apparatus fitted into a display window opening for protecting a portion of a display device, which is located under the display window opening in a casing of the electronic apparatus and exposed from the display window opening, the method comprising:
forming a plurality of decorating areas each including a window forming layer having a decorating portion formed in a portion of one surface of said hard coating film in a thin film state, in which a part not provided with said decorating portion is formed as a transparent window portion which transmits a portion of said display device exposed from said display window opening so as to be viewed, thereby producing a large size decorating film
sticking said large size decorating film to a large size transparent protective plate having an area larger than one of the decorating areas so that said decorating portion is located opposing to a surface of said large size transparent protective plate; and
cutting said stuck large size decorating film and large size transparent protective plate at one time in a position outer than said transparent window portion as well as inner side of the decorating area, thereby obtaining protection panels.

11. The display window protection panel for an electronic apparatus according to claim 2, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.

12. The display window protection panel for an electronic apparatus according to claim 3, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.

13. The display window protection panel for an electronic apparatus according to claim 4, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.

14. The display window protection panel for an electronic apparatus according to claim 5, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.

15. The display window protection panel for an electronic apparatus according to claim 6, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.

16. The display window protection panel for an electronic apparatus according to claim 7, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.

17. The display window protection panel for an electronic apparatus according to claim 8, wherein the transparent protective plate is constructed of a touch panel including a movable electrode film laminated on said decorating film and a fixed electrode plate stuck to said movable electrode film in the peripheral portion thereof so as to form an air layer between said movable electrode film and the fixed electrode plate.
